(19) United States
(12) Patent Application Publication
(10) Pub. No.: US 2010/0073048 A1
(43) Pub. Date: Mar. 25, 2010

(54) PHASE LOCKED LOOP AND CALIBRATION METHOD

(75) Inventors: Ling-Wei KE, Hsinchu County (TW); Tai-Yuan YU, Taoyuan County (TW); Hsin-Hung CHEN, Miaoli County (TW); Tser-Yu LIN, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/236,725

(22) Filed: Sep. 24, 2008

(51) Int. Cl. H03L 7/08

(52) U.S. Cl. 327/157

(57) ABSTRACT

A phase locked loop (PLL) directly uses a charge pump and loop filter therein for fast and low-costly calibration. The PLL comprises a charge pump, a loop filter, a voltage comparator, a counting device, and a calibration device. The loop filter comprises a voltage storage device coupled to the charge pump for charging by the charge pump, wherein the voltage storage device comprises a variable impedance. The voltage comparator is coupled to a voltage reference and to the voltage storage device for comparing a voltage of the storage device and a voltage of the voltage reference. The counting device is coupled to the voltage comparator to measure the charge time required for the voltage of the voltage storage device to substantially equal to the voltage of the voltage reference. The calibration device adjusts the variable impedance to adjust the time measured by the counting device to a desired time.

### BACKGROUND OF THE INVENTION

1. Field of the Invention

The invention relates to time constant calibration, and in particular to a method and apparatus for calibrating time constant of a phase locked loop and a system using the same.

2. Description of the Related Art

Phase locked loop (PLL) is a common form of frequency synthesizer used to generate frequency signals for use in an electronic or communication system. The PLL is generally designed to have a constant loop bandwidth, meeting requirements of noise suppression and lock time. The loop filter in the PLL generally comprises passive elements such as resistors and capacitors. The charge pump in the PLL generally provides a reference current determined by a current source and a reference resistor. However, variations inherent to resistors, capacitors or other elements in systems may lead to unacceptable variations in the loop bandwidth and gain, thus degrading noise suppression and lock time of the PLL.

There have been numerous approaches in conventional art to adjust the aforementioned undesired variations. Nonetheless, two of the prevailing calibration approaches are RC time constant calibration and RC time compensation calibration. The RC time constant calibration, for example proposed by Gehring (U.S. Pat. No. 6,842,710), performs RC time constant detection and RC time constant adjustment by binary/sequential search, thereby achieving frequency response calibration. However, according to Gehring's disclosure, a relatively longer time period is required to complete the calibration process due to a binary/sequential search mechanism. The RC time compensation calibration, for example proposed by Humphreys (U.S. Pat. No. 6,731,145), performs RC time detection and calculates RC time compensation by an operation or computation unit, thereby completing calibration process in one time (thus in a short period). Nonetheless, according to Humphreys' disclosure, the operation unit must also comprise a charging mechanism and a voltage storage mechanism, therefore resulting in relatively higher costs.

Accordingly, a novel approach is desired to adjust undesired variations inherent in resistors, capacitors or other elements in systems, which is faster and less costly than the conventional art.

### BRIEF SUMMARY OF INVENTION

An exemplary embodiment of a phase locked loop is disclosed, comprising a charge pump, a loop filter, a voltage comparator, a counting device, and a calibration device. The loop filter comprises a voltage storage device coupled to the charge pump for charging by the charge pump, wherein the voltage storage device comprises a variable impedance. The voltage comparator is coupled to a voltage reference and to the voltage storage device for comparing a voltage of the storage device and a voltage of the voltage reference. The counting device is coupled to the voltage comparator to measure the charge time required for the voltage of the voltage storage device to substantially equal to the voltage of the voltage reference. The calibration device adjusts the variable impedance to calibrate the time measured by the counting device to a desired time.

An exemplary embodiment of a method for calibrating a time constant for an integrated circuit or an electronic system is also disclosed, wherein the integrated circuit or the electronic system comprises a phase locked loop having a charge pump and a loop filter. The calibrating method comprises the steps of: charging a voltage storage device of the loop filter by a charge current from the charge pump; measuring a time required for a voltage of the voltage storage device to match a voltage of a voltage reference, wherein the charge time is dependent on an impedance of the loop filter; and adjusting the impedance of the loop filter to make the charge time substantially equal to a desired time constant value. It is noted the calibrating method further configuring a second circuit (excluding the phase locked loop) on the integrated circuit to have the desired constant value.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 schematically shows block diagrams of a phase locked loop according to an exemplary embodiment of the invention.

FIG. 2 shows exemplary implementation of a charge pump and a loop filter in the phase locked loop of the invention.

FIG. 3 is a flowchart of a method for calibrating time constant in an electronic system or integrated circuit according to an exemplary embodiment of the invention.

FIG. 4 is a flowchart showing another method for calibrating time constant in an electronic system or integrated circuit according to another exemplary embodiment of the invention.

FIG. 5 is a flowchart showing further another method for calibrating time constant in an electronic system or integrated circuit according to further another exemplary embodiment of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

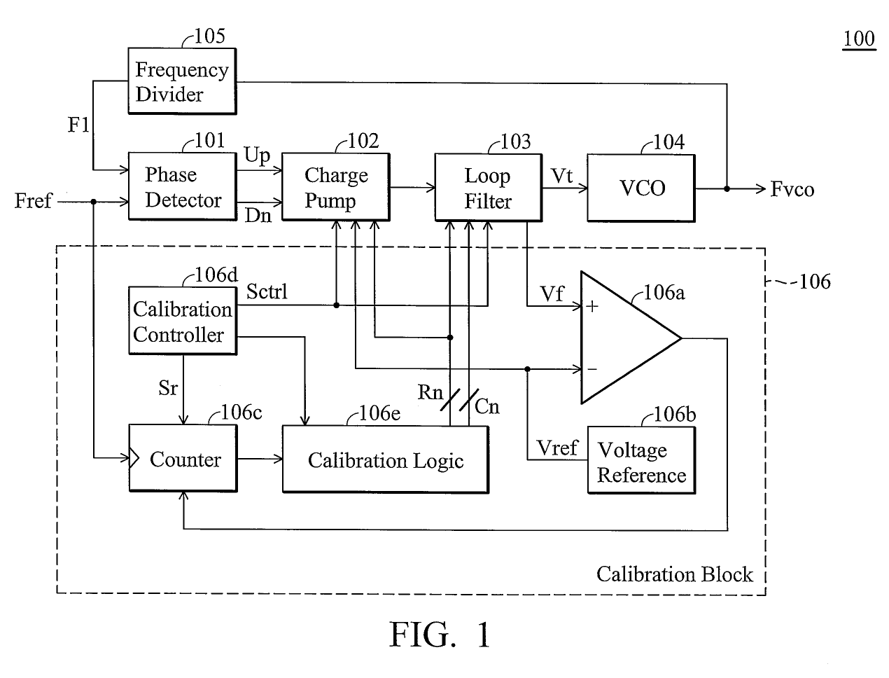

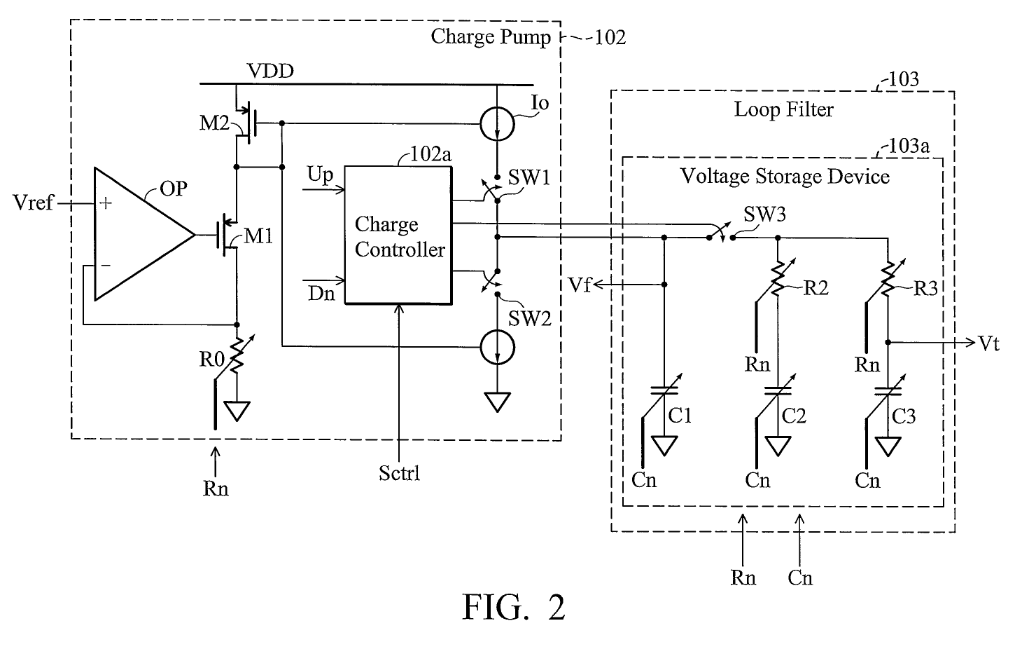

FIG. 1 is a phase locked loop according to an exemplary embodiment of the invention. The phase locked loop 100 comprises: a phase detector 101 receiving a reference frequency signal Fref and a first frequency signal F1 to generate phase difference signals Up and Dn, a charge pump 102 coupled to transfer the phase difference signals (Up/Dn) to a current signal; a loop filter 103 coupled to filter the current signal to generate a control signal Vt; a voltage controlled oscillator (VCO) 104 responsive to the control signal Vt to generate the output frequency signal Fvco; and a frequency divider 105 dividing the output frequency signal Fvco to generate the first frequency signal F1. It is noted that the loop filter 103 comprises a voltage storage device (shown in FIG. 2) coupled to the charge pump 102 for charging by the charge pump 102. The voltage storage device further comprises a variable impedance, which will be described in more detail later.

The phase locked loop 100 further comprises a calibration block 106 for carrying out calibration in conjunction with the charge pump 102 and the loop filter 103. The calibration block 106 comprises: a voltage comparator 106a coupled to a voltage reference 106b and to the voltage storage device (not shown in FIG. 1) for comparing a voltage (Vf) of the voltage storage device and a voltage (Vref) of the voltage reference; a counter 106c coupled to the voltage comparator 106a to measure a charge time Tch required for the voltage Vf of the voltage storage device to substantially equal to the voltage Vref of the voltage reference 106b; and a calibration device which comprises a calibration controller 106d and a calibration logic 106e, for adjusting the variable impedance to adjust the charge time Tch recorded by the counting device 106c to a desired time Td.

FIG. 2 shows an exemplary implementation of a charge pump and a loop filter in the phase locked loop 100 of the invention. The charge pump 102 comprises a charge controller 102a controlling switches SW1 and SW2 responsive to the phase difference signals Up and Dn for charging and discharging the loop filter 103, when the phase locked loop 100 operates in a frequency locking mode. When the phase locked loop 100 operates in a calibration mode, the calibration controller 106c controls the switches SW1, SW2 and a switch SW3 depicted in FIG. 2 via the charge controller 102a, by outputting a control signal Sctrl. The charge pump 102 comprises a current source which comprises an operational amplifier OP, MOS transistors M1, M2 (other transistors or resistors not shown in FIG. 2) and a resistor R0 to generating a current output (Io). The current output Io is determined by the resistor R0 and a second voltage reference, for example may be the voltage reference Vref.

The loop filter 103 comprises a voltage storage device 103a which has a variable impedance. In this exemplary implementation, the voltage storage device 103a (or the variable impedance) comprises a plurality of passive elements, such as capacitors C1˜C3 and resistors R2˜R3, but it is not limited thereto. The impedances of the resistors R2˜R3 and the capacitors C1˜C3 are adjustable, and thus the voltage storage device 103a equivalently comprises the variable impedance. Also the loop filter may comprise the switch SW3 for selectively connecting the capacitor C1 and the group of the capacitors C1˜C2 and resistors R1˜R2.

Operation of the phase locked loop 100 in the calibration mode will be described in detail with reference to FIGS. 1 and 2. First, the calibration controller 106d closes the switch SW2 and opens the switches SW1 and SW3 to initialize the voltage Vf of the capacitor C1 (or the voltage storage device). Secondly, the calibration controller 106d closes the switch SW1 and opens the switches SW2 and SW3. It is noted that the calibration controller 106d may control the switches SW1˜SW3 by sending a control signal Sctrl to the charge controller 102a. The calibration controller 106d can also directly control the switch SW3 by sending the control signal Sctrl to the loop filter 103. The calibration controller 106d also outputs a reset signal Sr to reset the counter 103c. Then, the current output Io starts to charge the capacitor C1 and the counter 106c begins counting. When the voltage Vf of the capacitor C1 becomes equal to or exceeds the voltage Vref of the voltage reference 106b, the voltage comparator 106a drives the counter 106c to stop counting. Then, the charge time Tch required for the voltage Vf of the capacitor C1 (or the voltage storage device 103a) to substantially equal to the voltage Vref is measured by the counter 102c.

The calibration logic 106e calculates a compensation time Tcom according to the desired time Td and the measured charge time Tch, and selectively adjusts impedances of the capacitors C1˜C3 and resistors R2˜R3 for compensating the measured charge time Tch to the desired time Td. The calibration logic 106e may comprise a mapping logic (not shown in FIG. 1) to convert the compensation time Tcom into adjusting signals Rn and Cn to tune impedances of the capacitors C1˜C3 and resistors R2˜R3. In this exemplary implementation, the switch SW3 in the voltage storage device 103a is closed by the calibration controller 106d to adjust the impedance of the voltage storage device 103a. It is noted that the resistor R0 may be adjusted for tuning the current output Io by the adjusting signal Rn, thereby compensating the measured charge time Tch.

When the phase lock loop 100 operates in the frequency locking mode, the charge controller 102a controls the switches SW1 and SW2 for charging and discharging the loop filter 103 according to the phase difference signals Up and Dn. In addition, the switch SW3 closes such that the voltage storage device 103a obtains a required RC time constant responsive to the desired time Td, thereby generating the control signal Vt for the VCO 104 to generate the output carrier signal Fvco.

Another exemplary embodiment of the invention provides a method for calibrating a time constant for an electronic system or an integrated circuit which comprises a phase locked loop. Conceptually, the calibrating method comprises the steps of: charging a voltage storage device of a loop filter of the phase locked loop by a charge current from the charge pump of the phase locked loop; measuring a time required for a voltage of the voltage storage device to match a voltage of a voltage reference, wherein the charge time is dependent on an impedance of the loop filter; adjusting the impedance of the loop filter to make the charge time substantially equal to a desired time constant value. If other circuit portions (excluding the phase locked loop), in the electronic system or integrated circuit, operate based on timing signals correlated to the desired time constant value, the method for calibrating a time constant for an electronic system or an integrated circuit may further comprise the step of: configuring the other circuit portions to have the desired constant value characterized by the desired time constant.

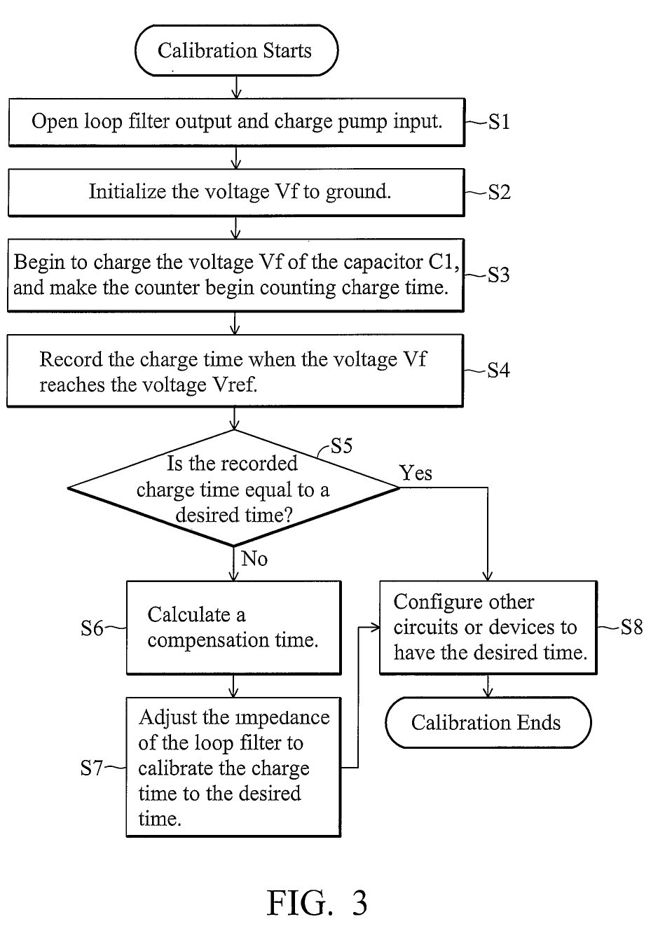

FIG. 3 is a flowchart of a method for calibrating time constant in an electronic system or integrated circuit according to an exemplary embodiment of the invention. The method for calibrating time constant in an electronic system or integrated circuit is appropriate for an electronic system or integrated circuit comprising a phased locked loop. It is noted that the calibrating method in FIG. 3 corresponds to the operations of the calibration block 106 in FIG. 1 and the charge pump 102 and loop filter 103 in FIG. 2, but it is not limited thereto. In the following paragraphs, the method for calibrating time constant in an electronic system or integrated circuit will be described in detail with reference to FIGS. 1˜3.

The method for calibrating time constant in an electronic system or integrated circuit begins by opening the loop filter (103) output and charge pump (102) input, in step S1. For example, the calibration controller 106d opens switches SW3 to open the loop filter output, and controls the charge controller 102a to not receive the phase difference signals Up and Dn. Secondly, the voltage of the loop filter 103 is initialized (or discharged) to ground, in step S2. For example, the calibration controller 106d closes SW2 such that the voltage Vf of the capacitor C1 (or the voltage storage device 103a) is discharged to ground. Then, the charge pump 102 begins to charge the voltage Vf of the capacitor C1, and the counter 106c begins counting the charge time of the capacitor C1, in step S3. Next, the charge time for the voltage Vf of the capacitor C1 to reach the voltage Vref of the voltage reference 106b is recorded, in step S4. In step S5, it is determined whether the recorded charge time is equal to a desired time (or a desired time constant value). If the recorded time is not equal to the desired time, a compensation time is calculated, in step S6. Note that the steps S5, S6 and S7 can be performed by the calibration logic 106e. Subsequently, the impedance of the loop filter 103 is adjusted to calibrate the charge time to the desired time, in step S7. For example, adjusting impedance may be performed by tuning and combining the capacitors and resistors by control of the adjusting signals Rn and Cn and connection of the switch SW3, as described in FIG. 2. Finally, other circuits or devices in the integrated circuit (or the electronic system), excluding the phase locked loop, are configured to have characteristics according to the desired time (or the desired time constant value), in step S8. In step S5, if the recorded time is equal to the desired time, them step S8 is performed.

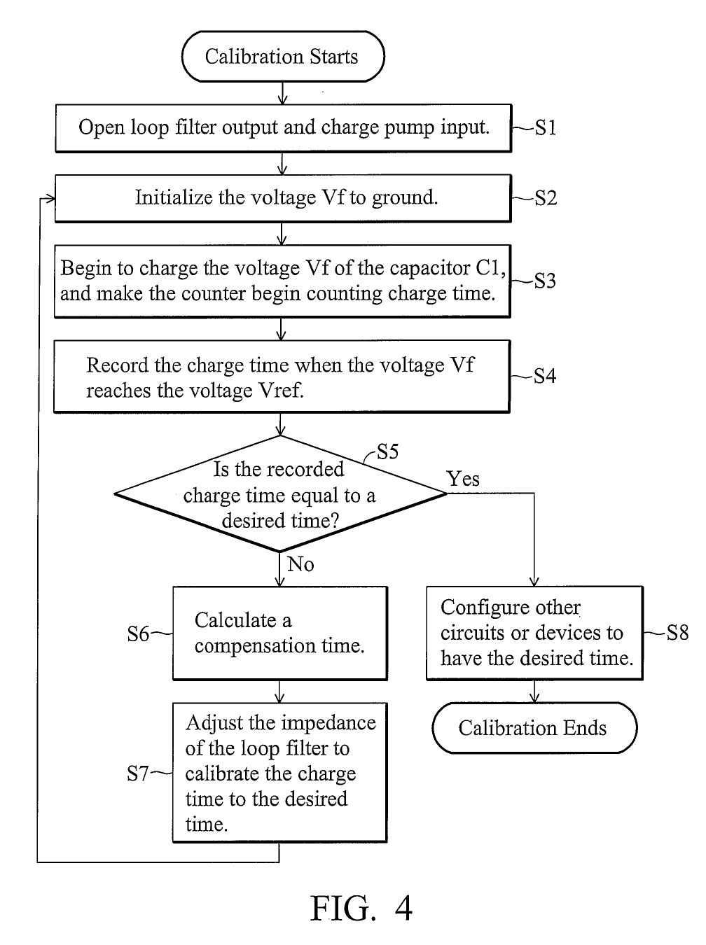

The method described in FIG. 3 performs one time computation without desired time re-check. A variation of the method in FIG. 3 to perform one time computation with desired time re-check is described in FIG. 4.

FIG. 4 is a flowchart showing another method for calibrating time constant in an electronic system or integrated circuit according to another exemplary embodiment of the invention. The main difference between the two flowcharts in FIGS. 3 and 4 is the step adopted after performing step S7. In step S7 of FIG. 4, the impedance of the loop filter 103 is adjusted to calibrate the charge time to the desired time, as described in FIG. 3. After step S7, however the step flow goes to step S2, but not step S8, whereby the desired time will be re-checked again in the following step S5.

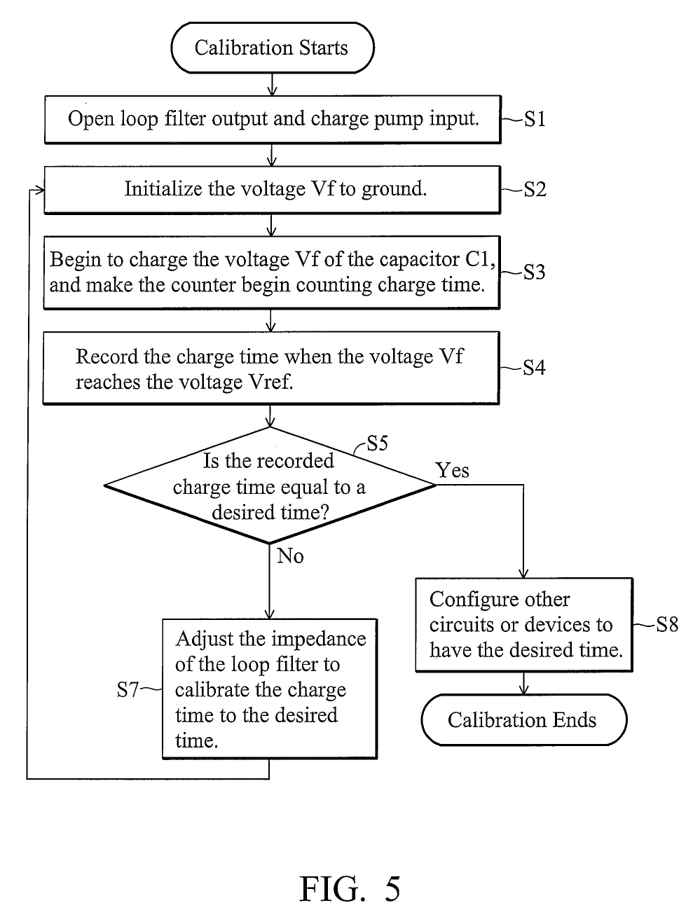

FIG. 5 is a flowchart showing further another method for calibrating time constant in an electronic system or integrated circuit according to further another exemplary embodiment of the invention. The main difference between the two flowcharts in FIGS. 4 and 5 is that step S6 in FIG. 4 is omitted in FIG. 5. FIG. 5 can be seen as a procedure of successive approximation registering (SAR) until near desired time.

In step S5 of FIG. 5, it is determined whether the recorded charge time is equal to a desired time (or a desired time constant value), as described in FIG. 4 (or FIG. 3). If the recorded time is not equal to the desired time, step S7 is then performed. In step S7 of FIG. 5, the impedance of the loop filter 103 is adjusted to calibrate the charge time to the desired time, as described in FIG. 4. After step S7, the step flow goes to step S2, as described in FIG. 4. The steps of S2→S5→S7→S2 . . . are repeated until the recorded charge time (i.e., the candidate of the desired time) is successively approximated to the desired time.

According to the disclosure of the invention, time constant calibration is performed without a binary/sequential search mechanism, thereby achieving faster calibration than the conventional art. Also, the disclosure of the invention directly uses a charge pump and a loop filter in the phase locked loop for calibration, without an additional charge mechanism and voltage storage mechanism as required in the conventional art, thereby reducing the costs for calibration.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase locked loop, comprising:
a charge pump;
a loop filter comprising a voltage storage device coupled to the charge pump for charging by the charge pump, wherein the voltage storage device comprises a variable impedance;
a voltage comparator coupled to a voltage reference and to the voltage storage device for comparing a voltage of the storage device and a voltage of the voltage reference;
a counting device coupled to the voltage comparator to measure the charge time required for the voltage of the voltage storage device to substantially equal to the voltage of the voltage reference; and
a calibration device for adjusting the variable impedance to calibrate the time measured by the counting device to a desired time.

2. The phase locked loop as claimed in claim 1, wherein the variable impedance comprises a plurality of passive elements whose impedances are adjustable through the calibration device.

3. The phase locked loop as claimed in claim 2, further comprising a switch controlled by the calibration device to calibrate the time measured by the counting device to the desired time by connecting a first group and a second group of the passive elements.

4. The phase locked loop as claimed in claim 1, wherein the charge pump comprises a current source generating a current output thereof, and the current output is determined by a resistance and a second voltage reference.

5. The phase locked loop as claimed in claim 4, wherein the resistance is adjustable by the calibration device for calibrating the time measured by the counting device.

6. The phase locked loop as claimed in claim 1, wherein the calibration device further comprises a calibration controller to control charging and discharging of the voltage storage device and to start and reset the counting device to begin a counting when the charge pump begins charging the voltage storage device.

7. The phase locked loop as claimed in claim 1, wherein the calibration device further comprises a calibration logic to calculate a compensation time according to the desired time and the measured time and adjusting the variable impedance according to the compensation time.

8. A method for calibrating a time constant for an electronic circuit comprising a phased locked loop which comprises a charge pump and a loop filter, the method comprising:
charging a voltage storage device of the loop filter by a charge current from the charge pump;
measuring a time required for a voltage of the voltage storage device to match a voltage of a voltage reference, wherein the charge time is dependent on an impedance of the loop filter; and
adjusting the impedance of the loop filter to make the charge time substantially equal to a desired time.

9. The method for calibrating a time constant as claimed in claim 8, wherein the impedance comprises a plurality of passive elements disposed in the loop filter.

10. The method for calibrating a time constant as claimed in claim 9, wherein the plurality of the passive elements are adjustable and selectively combinable to form a variable impedance.

11. A method for calibrating a time constant for an integrated circuit comprising a phased locked loop, comprising:
charging a voltage storage device of a loop filter of the phase locked loop by a charge current from the charge pump;
measuring a time required for a voltage of the voltage storage device to match a voltage of a voltage reference, wherein the charge time is dependent on an impedance of the loop filter;
adjusting the impedance of the loop filter to make the charge time substantially equal to a desired time constant value; and
configuring a second circuit on the integrated circuit to have the desired constant value.

12. The method for calibrating a time constant for an integrated circuit as claimed in claim 11, wherein the impedance comprises a plurality of passive elements disposed in the loop filter.

13. The method for calibrating a time constant for an integrated circuit as claimed in claim 12, wherein the plurality of the passive elements are selectively combinable to form a variable impedance.
